(19) United States
(12) Patent Application Publication
(10) Pub. No.: US 2026/0332206 A1
(43) Pub. Date: Oct. 22, 2026

(54) Power Saving Base Station

(71) Applicant: Matsing, Inc., Irvine, CA (US)

(72) Inventor: Richard Neil Braithwaite, Orange, CA (US)

(21) Appl. No.: 19/641,024

(22) Filed: Apr. 7, 2026

Related U.S. Application Data
(60) Provisional application No. 63/789,593, filed on Apr. 16, 2025.

(51) Int. Cl. H04B 7/06; H03F 3/24

(52) U.S. Cl. CPC H04B 7/0617; H03F 3/245; H03F 2200/451

(57) ABSTRACT

Apparatus, systems, and methods are described for fixed multiple beam antenna systems where a non-null subset of beams is inactive at any given time, and each beam/polarization is fed by a separate digital channel through a Cat-A (non-beamforming) radio unit. A powered device has a number of power amplifiers (PAs), where each input port has an associated output port that forms a radio frequency (RF) path. The powered device has internal routing so that all PAs contribute power when a single beam is active. Digital channels are turned on and off to switch the selected beams. To reduce post-PA losses, switching is done on the low power side of the PAs. Significant benefits are that a single beam has more power than an individual PA, and there is better utilization of the PAs when only one RF path of the powered device is used.

This application claims priority to US provisional application 63/789,593, filed Apr. 16, 2025, the entire disclosure of which is incorporated herein by reference.

### FIELD OF THE INVENTION

The field of the invention is base station antennas.

### BACKGROUND

The background description includes information that may be useful in understanding the present invention. It is not an admission that any of the information provided herein is prior art or relevant to the presently claimed invention, or that any publication specifically or implicitly referenced is prior art.

A base station in 5G is referred to as a gNodeB (gNB) and a mobile device is referred to as user equipment (UE). In a 5G O-RAN system, the gNB includes a distributed unit (DU) that transmits and receives digital data through several radio units (RUs), which are also part of the gNB. The RU connects to antenna (ANT) ports that have radiating elements transmitting and receiving signals to/from UEs within the cell. FIG. 1 is a block diagram showing a gNB, whose key components are the DU, RU, and ANT, communicating with a UE over a radio frequency (RF) channel. This disclosure focuses on the DU, RU, and ANT performing beamforming within a fixed multiple beam network. Power and cost saving options are presented suited to a beam sweep, where one beam is active at any given time, but each beam is active at some time over a longer cycle. The saving options are also suitable for beam switching where two or more active beams are switched between two or more disjoint beam states.

The RU for the downlink comprises a transceiver (TRX) that converts digital data from the DU to a low power RF signal and a power amplifier (PA) that increases the power level for transmission at the antenna. The RU for the uplink comprises a low noise amplifier (LNA) that amplifies a low power RF signal received by the antenna and a transceiver that converts the RF signal to digital data sent to the DU. A circulator, transmit/receive (T/R) switch, or duplexer is used to separate the uplink and downlink signals within the RU so that the antenna may be used for both uplink and downlink. A block diagram of the RU and antenna for a lens beamforming solution is shown in FIG. 2.

Assume the RU is 8T8R, where 8T refers to the number of transmit channels and 8R refers to the number of receive channels. For a lens beamforming solution, that corresponds to 4 beam directions with two polarizations per beam. In fixed beam applications, it is often the case that fewer beams are transmitted simultaneously than the four beams available. For example, one beam could be used for transmission during a given slot, but the beam selection changes with each slot to cover the entire cell. It is referred to as a beam sweep when the beams are selected sequentially, as shown in FIG. 3A. A second example, referred to as beam switching, has two beam states where either beam 1 and beam 3 are active simultaneously or beam 2 and beam 4 are active simultaneously, as shown in FIGS. 3B and 3C.

The selection of the active beam is done in the DU when the RU is based on an O-RAN Cat-A split. For the downlink, a Cat-A RU receives up to 8 data channels from the DU, converting each to a RF signal. The DU includes a precoder matrix that weights the individual channels. For beam selection, the precoder matrix functions as a switch turning beams on or off. It is possible to select the beam in the RU using switches if more beams are available than number of data channels from the DU.

For a beam sweep, savings are possible by reducing the number of PAs to match the twice number of active beams (for dual polarization) instead of the number of antenna ports. Reducing the number of PAs and sharing them amongst several channels provides cost and power savings Assume the RU has two PAs (one per polarization). The number of transceivers and antenna elements remain the same, which is 8 in this example. A means to route the RF signals from the transceivers, through the two available PAs, to the active antenna elements is needed. Switching is a method to route the RF. The necessary RF switching is located between the circulators and the antennas, as shown in FIG. 4. Switching is also used on the lower power side (input) of the PAs.

Switching networks have challenges. The active beam in 5G can change every slot (1 ms or less). Mechanical switches are not feasible due to limitation in switching speed and reliability (maximum number of switching cycles is too low). Other switches are available that are more robust to rapid and frequent switching. External switching requires synchronization with the slot boundaries of the digital signal.

An important issue with any passive device between the PA and antenna, such as a switch, is insertion loss. PAs tend to be the most expensive part of the RU and the price increases with power. It is desirable to maximize the amount of power reaching the antenna by minimizing post-PA losses. Insertion losses between the antennas and LNAs in the receive path are problematic as well because such losses increase the noise figure of the receiver, which in turn decreases SINR and throughput. Low insertion loss pre-LNA is therefore important. Note that insertion losses before the PA and after the LNA are less concerning because the power loss in the transmission path is low and the impact on the overall noise figure of the receive path is low.

Thus, there is still a need for a method/apparatus to use the available PAs efficiently when a subset of the available beams is active and perform beam selection on the low power side of the PAs to minimize post-PA insertion losses.

### SUMMARY OF THE INVENTION

The inventive subject matter provides apparatus, systems, and methods in fixed multiple beam antenna system where a non-null subset of beams is inactive at any given time, and each beam/polarization is fed by a separate digital channel through a Cat-A (non-beamforming) RU.

In preferred embodiments a powered device has a number of power amplifiers (PAs), where each input port has an associated output port that forms a RF path. The powered device has internal routing so that all PAs contribute power when a single beam is active.

Digital channels are turned on and off to switch the selected beams. To reduce post-PA losses, switching is done on the low power side of the PAs.

Significant benefits are that a single beam has more power than an individual PAs, and there is better utilization of the PAs when only one RF path of the powered device (balanced amplifier below) is used.

Various objects, features, aspects, and advantages of the inventive subject matter will become more apparent from the following detailed description of preferred embodiments, along with the accompanying drawing figures in which like numerals represent like components.

### BRIEF DESCRIPTION OF THE DRAWINGS

FIG. 1 depicts a diagram of a 5G base station (gNB) and user equipment (UE) connected by a RF channel.

FIG. 2 depicts a diagram of a distributed unit (DU), radio unit (RU), and antenna (ANT) for lens beamforming.

FIG. 3A depicts a diagram of a beam sweep where one beam is active for any given time and the active beam changes each time slot.

FIGS. 3B and 3C depict a diagram of beam switching between two disjoint beam states.

FIG. 4 depicts a diagram of switching networks to reduce PA count.

FIG. 5 depicts a diagram of a balanced amplifier (four-port powered device) within a single transmit path to a single antenna port.

FIG. 6 depicts a diagram of a balanced structure with two transmit paths and two receive paths.

FIG. 7 depicts a diagram of a balanced structure with two transmit paths and two receive paths where first hybrid coupler is implemented in the digital domain.

FIG. 8 depicts a diagram of an alternative balanced structure with two transmit paths and two receive paths where first hybrid coupler is implemented in the digital domain.

FIG. 9 depicts a diagram of an expanding the balanced structure to 4 PA using additional hybrid couplers to create an 8-port device; four circulators and receive paths have been omitted for clarity.

FIG. 10 depicts a diagram expanding the balanced structure to 4 PA using Bulter matrices to create an 8-port powered device. The four circulators and receive paths have been omitted for clarity.

FIG. 11 depicts a diagram of signals at antenna ports 1 and 2 when the structure is not balanced.

FIG. 12 depicts a diagram of adding an imbalance correction block to compensate for imbalances.

FIG. 13 depicts details of an imbalance correction block.

FIG. 14 depicts a diagram of imbalance correction using output power measurements for coefficient estimation.

FIGS. 15A and 15B depict beam switching examples for non-MIMO applications.

FIGS. 16A and 16B depict beam switching example for MIMO applications.

FIG. 17 depicts a diagram of a two balanced amplifiers used to amplify the four beams.

FIGS. 18A and 18B depict a beam sweep with one active beam.

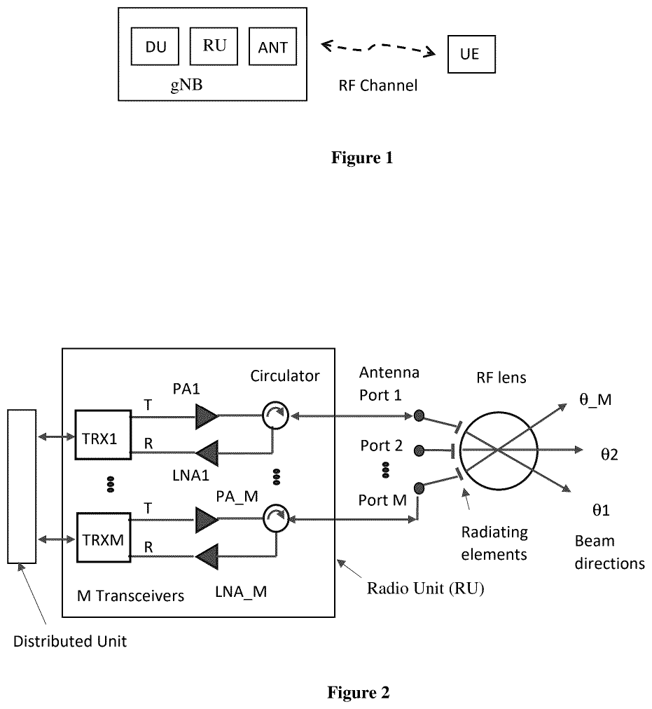

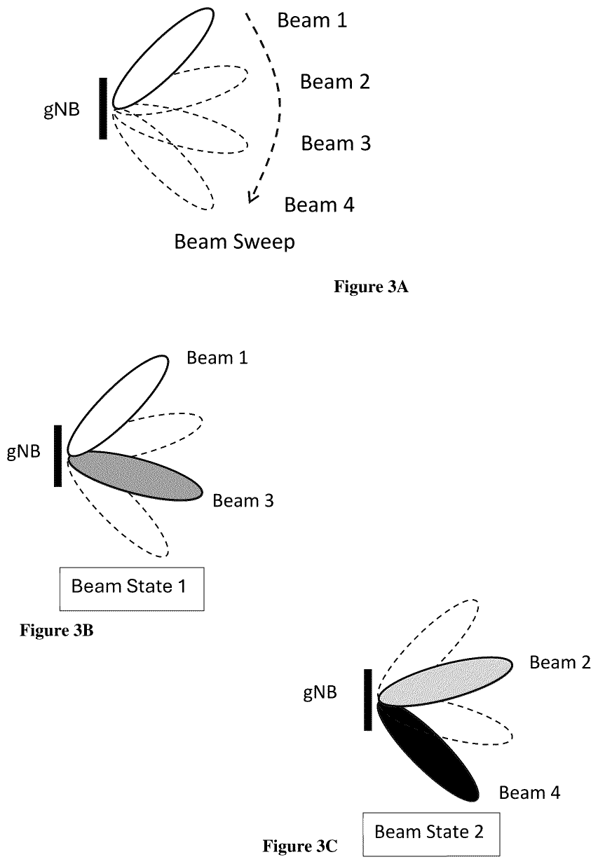

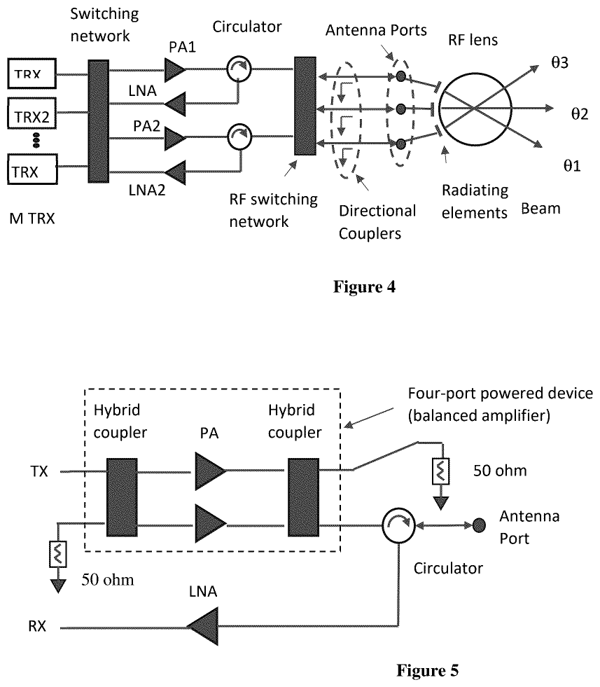

### DETAILED DESCRIPTION

Antenna systems are disclosed having multiple (e.g., 2-100) fixed beams, with a subset of the fixed beams being inactive (e.g. not transmitting, not broadcasting, etc.) at any given time. The system includes a distributed unit (DU) that transmits digital data through a more than one radio units (RUs). One of the radio units includes multiple transceivers that convert each channel from multiple digital channels into a low power RF signal, respectively. The system further includes a powered device having multiple paired input and output ports and multiple power amplifier (PAs). In some embodiments the number of PAs equals the number of paired input and output ports. The powered device is configured such that (i) each input port and associated output port form a RF path and (ii) more than one PA concurrently contributes power to an active digital channel selected from the multiple digital channels.

The active digital channel is typically defined, selected, determined, or propagated by the distributed unit (DU), though in some embodiments the active digital channel is defined, selected, determined, or propagated by the radio unit (RU).

The powered device typically includes a balanced amplifier that includes an input hybrid coupler, more than one PA (e.g., 2-100), and an output hybrid coupler. The input hybrid coupler is typically defined in a digital domain, while the input hybrid coupler is typically defined in a RF domain.

In some embodiments the powered device has four input ports and four output ports, four input hybrid couplers, four PAs, and four output hybrid couplers. Similarly, some embodiments have the same number of input ports, output ports, input hybrid coupler, PA, and output hybrid coupler. At least one of the input hybrid couplers is defined in the digital domain, while at least one of the input hybrid couplers is defined in the RF domain.

A powered device with four input ports and four output ports can also include an input Butler matrix, four PAs, and an output Butler matrix. The input Butler Matrix is typically defined in the digital domain, while the input Butler Matrix is defined in the RF domain.

In some systems one, some, or all of the multiple fixed beams pass through a lens beamformer.

Further systems with multiple fixed beams are contemplated. Such systems include a powered device configured to receive or transmit a multiple channels and a digital modifier. The powered device includes multiple pairs of input and output ports, such that a path between each pair of input and output ports forms a RF path. The powered device also includes multiple power amplifiers (PAs) disposed inside the powered device and configured such that more than one PA contributes power when one channel from the plurality of channels is active. The power device also includes a directional coupler coupled with each of the plurality of output ports and configured to measure an imbalance between each path. The digital modifier compensates for the imbalances of the powered device.

Typically the digital modifier uses a precoder matrix of a distributed unit (DU) coupled with the power device, but the digital modifier can be part of a radio unit (RU) transceiver.

The powered device can include a balanced amplifier having an input hybrid coupler, more than one PA (e.g., 2-100), and an output hybrid coupler. The input hybrid coupler is typically defined in the digital domain. One, some, or all of the multiple fixed beams pass through a lens beamformer.

Solutions include using a balanced amplifier structure for more efficient switching. A balanced amplifier comprises an input hybrid coupler, two power amplifiers (PAs), and an output hybrid coupler. This creates a four-port powered device where there are two input RF ports and two output RF ports. In a typical implementation, one input port and one output port are terminated with 50 ohms so the maximum power at the output is double that of an individual PA. A balanced amplifier within a single transmit path to a single antenna port is shown in FIG. 5. Note the input and output ports of the balanced amplifier have a reverse order (upper input port corresponds to the lower output port). Also shown in FIG. 5 is a single receive path from the antenna port that includes the circulator and LNA.

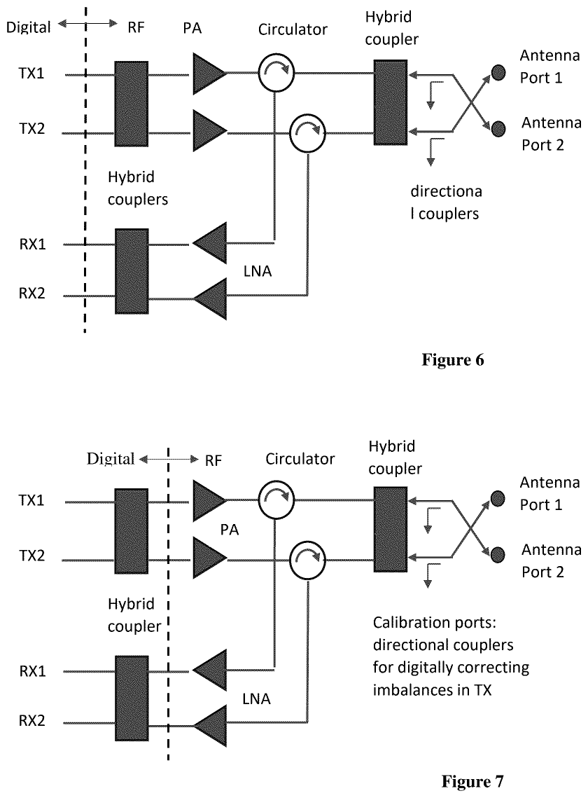

The balanced structure can be modified to allow switching to be applied on the low power side of the PAs, in the digital domain within the DU. Consider the block diagram found in FIG. 6. If you put a Tx signal on port TX1 and no signal on port TX2, the signal appears on antenna port 1. Both PAs contribute power. If you put a signal on port TX2 and no signal on port TX1, the signal appears on antenna port 2. If you put signals on both ports TX1 and TX2, you get signals on both antenna port 1 and antenna port 2, but at a reduced maximum power at each antenna (total maximum power remains the same). Since the receive signals from the antennas are needed, a circulator is placed between each PA and the output hybrid. The benefit is that the power ratings for the PAs and the circulators are reduced by half. In addition, since the switching is done in the digital domain within the DU, synchronization with the slot boundaries is trivial because the data and switching use the same sampling clock.

If it is assumed that the PAs are 40 W, as well as the circulators, then 80 W is available at the active antenna in the first two cases. The maximum power per antenna is reduced in the third case, but the maximum total power from the two antennas is still 80 W. The benefit is smaller PAs and the switching is done before the amplifier. Insertion losses before the PA are less significant than after it.

An improvement is to perform the hybrid coupling on the left side digitally, as shown in FIG. 7. The precoder matrix in the DU can implement the digital equivalent of a hybrid coupler. Alternatively, this can be done within the RU transceivers. A directional coupler can be added after the hybrid on the antenna side to provide a signal for use in calibration to correct digitally any imbalance in the hybrid or insertion phase mismatch in the circulators. Calibration is discussed later.

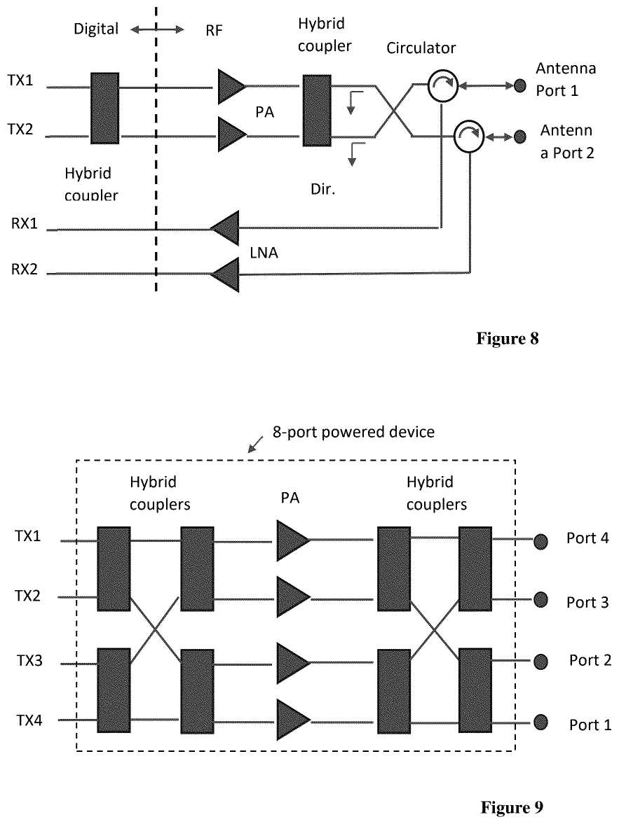

An alternative implementation is to move the circulators closer to the antenna ports, at the output of the second hybrid coupler, as shown in FIG. 8. The advantage of this structure over that shown in FIG. 7 is that phase mismatches in the circulators are no longer a problem and the circulator improves the 50-ohm match at the second hybrid coupler output. There is also less insertion loss on the receive path before the LNA. The disadvantage is that the power rating of the circulators needs to be doubled to 80 W.

The balanced structure can be expanded to four PAs by using additional hybrid couplers, as shown in FIG. 9. This creates an eight-port powered device where there are four input RF ports and four output RF ports. If you put a Tx signal on port TX1 and no signal on the remaining ports, the signal appears on antenna port 1. All four PAs contribute power to antenna port 1, four times that of an individual PA. Similarly, if you put a signal on any TX port, and no signal on the remaining TX ports, the output signal appears at the corresponding antenna port. If you put signals on several TX ports, you get signals on the corresponding antenna ports, but at a reduced power at each antenna. Note that the order of the output ports is reversed relative to the input ports. Not shown in FIG. 9 are the receive signals from the antennas that require circulators to be placed somewhere between the PAs and the antenna ports. This is omission is done for clarity. The actual positions of the circulators could be after the PA and before the first column of output hybrid couplers, between the two columns of output hybrid couplers, or after the last column of hybrid couplers and before the antenna ports.

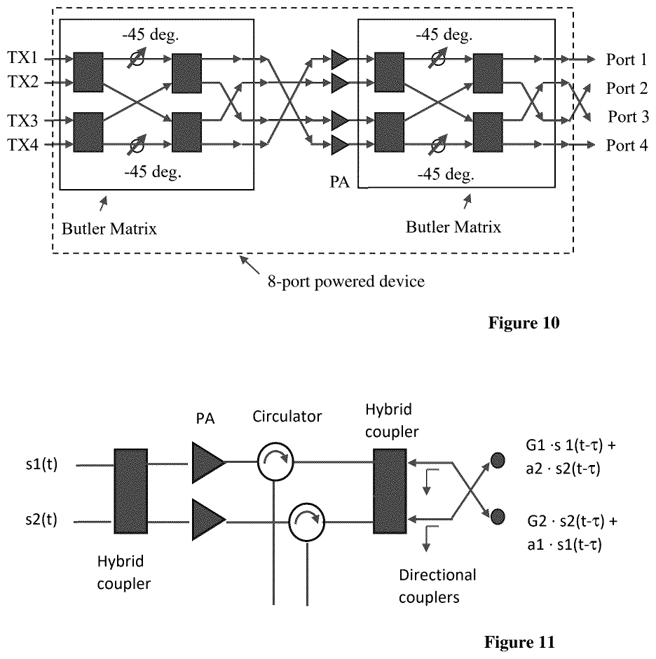

Alternatively, the balanced structure can be expanded to four PAs by using Butler matrices, as shown in FIG. 10. This creates an eight-port powered device where there are four input RF ports and four output RF ports. The power amplifiers are placed between two Butler matrices. The advantage of using Butler matrices is that they are available in a single package, reducing the space needed to implement the 4 PA structure. As in the previous case, if you put a signal on any TX port, and no signal on the remaining TX ports, the output signal appears at the corresponding antenna port. If you put signals on several TX ports, you get signals on the corresponding antenna ports, but at a reduced power at each antenna. Not shown in FIG. 10 are the receive signals from the antennas that require circulators.

In both FIG. 9 and FIG. 10, the components located on the low power side of the PAs (left side in the figures shown) can be implemented in the digital domain, using the precoder matrix within the DU or within the RU transceivers, or in RF domain.

Consider the case when two or more beams are active simultaneously. The two PA balanced structure is a good match for the lens beamformer. Neighboring beams in the azimuth direction tends to overlap, which means it is not likely that both neighboring beams would be used simultaneously during single user (SU-) or multiple user (MU-) MIMO. The proposed balance structure pairs neighboring beams of the same polarization. Neighboring beams might be used simultaneously if the same signal is transmitted on both beams to improve SINR for a UE located between the two beam directions. This is still possible using the balanced structure proposed, but the power per antennas is reduced.

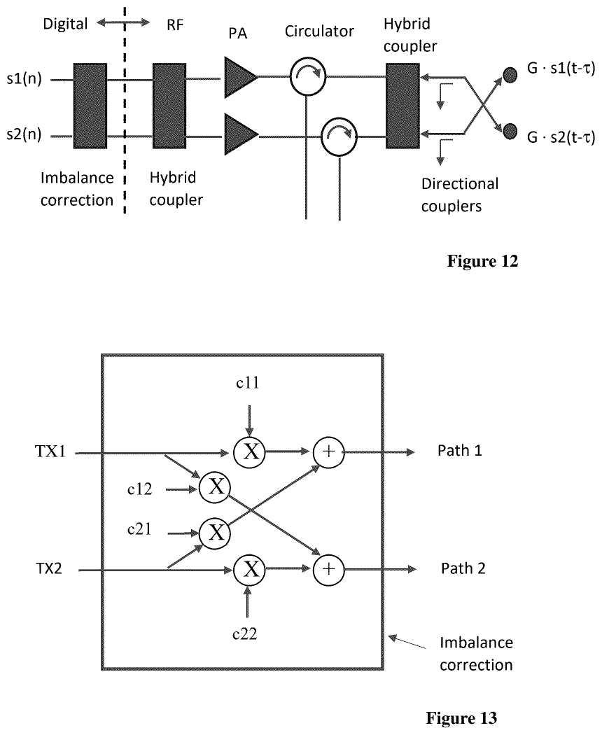

Let us now look at calibration. Assume the digital (sampled) signals s1(n) and s2(n) are inputs to ports TX1 and TX2, where n is the sample index. They are converted to low power RF signals, s1(t) and s2(t). The RF signals at antenna ports 1 and 2 will be G1·s1(t−τ)+a2·s2(t−τ) and G2·s2(t−τ)+a1·s1(t−τ), as shown in FIG. 11, where τ is a time delay. G1 and G2 are the gain of the balanced structure for path 1 and path 2. The values of a1 and a2 are cross-couplings resulting from imbalances in the structure. Ideally, G1=G2 and a1=0 and a2=0. Calibration using measurements from the directional couplers are used to estimate the correction needed. The imbalance correction is applied in the digital domain, preferably using the precoder matrix within the DU or within the RU transceivers, prior to the first hybrid coupler, as shown in FIG. 12.

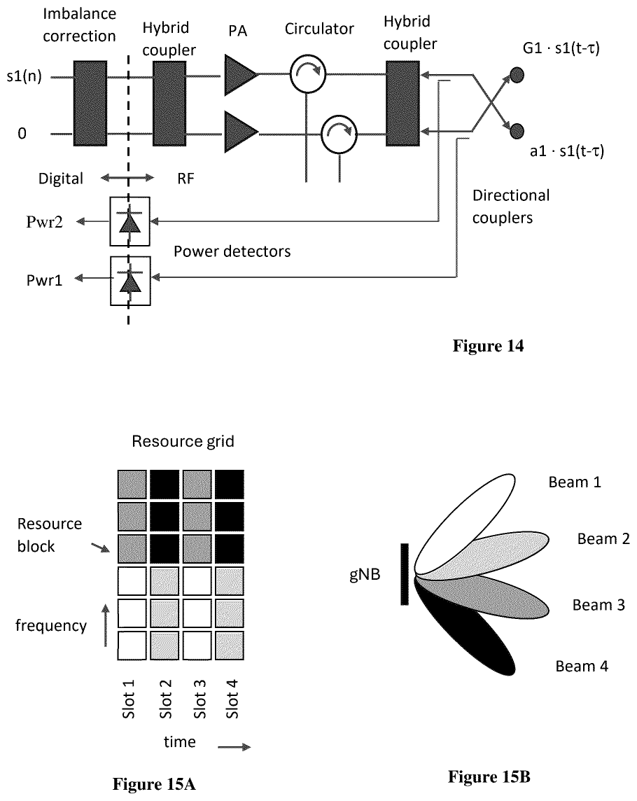

The details of the imbalance correction block are shown in the FIG. 13. The coefficients c11 and c22 are the gain corrections for path 1 and path 2. The remaining coefficients, c12 and c21, are corrections for cross-coupling between path 1 and path 2. The estimation of the coefficients is done based on measurements from the directional couplers that are fed back using observation receivers that convert the RF signal to digital. Alternatively, the directional couplers could be connected to power detectors whose output is digitized as a measurement for the coefficient estimator, as shown in FIG. 14. Note that the coefficients are complex values.

FIG. 14 depicts the case where a signal s1(n) is applied to port TX1 and no signal is applied to port TX2. In this case, the coefficient c12 in the imbalance correction block is adjusted to minimize the detected power on path 2 (through the directional coupler) so that a1=0. The residual power measured is due to uncorrelated noise only. The amplitude of coefficient c11 is adjusted so that the gain G1 is the desired value G. The coefficients c21 and c22 are adjusted in a similar manner when s2(n) is applied to TX2 and no signal is applied to TX1. In this case, c21 adjustments minimize the detected power on path 1 (through the directional coupler) and the amplitude of c22 is adjusted to make G2=G. The phases of c11 and c22 can be adjusted if path 1 and path 2 require phase alignment. This would be done off-line with a separate calibration process.

An alternative to using power detectors is to use observation receivers to fully demodulate and digitize the signals G1 ·s1(t−τ)+a2·s2(t−τ) and G2·s2(t−τ) +a1 ⋅ s1(t-t). The digital outputs are denoted by s1out(n) and s2out(n). Assume s1(n) and s2(n) are delayed within the estimator to be time-aligned with s1out(n) and s2out(n). Cross-correlations s1(n)·s1out*(n), s1(n)·s2out*(n), s2(n)·s1out*(n), and s2(n)·s2out*(n) are used to estimate the adjustment to the coefficients, including phase alignment of the two paths using the phases of coefficients c11 and c22.

In the following, examples are provided on how the balanced amplifier is used in a 5G O-RAN Gnb downlink. Also discussed is how the scheduler within the DU best assigns resources in a fixed wireless network using balanced amplifiers. The waveform used in 5G is based on OFDM. An OFDM symbol spans a time interval and has several sub-carriers that span the allocated bandwidth (BW). A slot is defined as 14 symbols that spans 1 ms when the sub-carrier spacing (SCS) is 15 kHz. A resource block (RB) is defined as 12 sub-carriers and N_{sym} symbols, where N_{sym}=14 is typical. The resource block is the smallest unit that the scheduler within the DU uses for DL grants to a given UE. A resource grid is used to represent the available RBs for the DU to schedule.

In the simplest case, a resource block is assigned to one UE. When spatial diversity allows more than one feasible RF channel exists, MIMO processing can be used. In such cases, a resource block is allocated to two or more RF channels (with independent data), increasing the data throughput. This is referred to as layers in 5G. If two or more layers are allocated to the same UE, it is referred to as single user (SU-) MIMO. If layers are allocated to different Ues, it is referred to as multi-user (MU-) MIMO.

Consider the case of an 8T8R RU with four beams and two polarizations. For convenience only one polarization will be considered. Beam switching for non-MIMO applications (one layer) schedules RBs to Ues best served by beam 1 and beam 3 during odd numbered slots. This is referred to as beam state 1. For beam state 2, RBs are scheduled to Ues best served by beam 2 and beam 4 during even numbered slots. An example of such scheduling is shown in FIG. 15. Neighboring beams are not active in this scheduling approach.

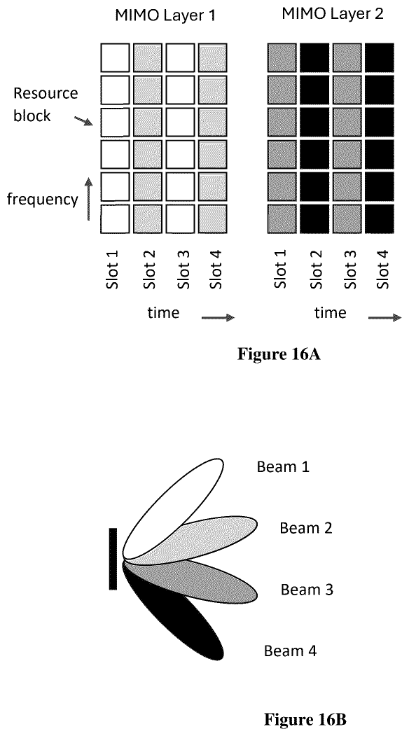

Beam switching can be used in combination with SU-or MU-MIMO, where beam 1 and beam 3 are used for the two MIMO layers in the first beam state and beam 2 and beam 4 are used for the two MIMO layers in the second beam state. An example of such scheduling is shown in FIG. 16. Neighboring beams are not active in this scheduling approach.

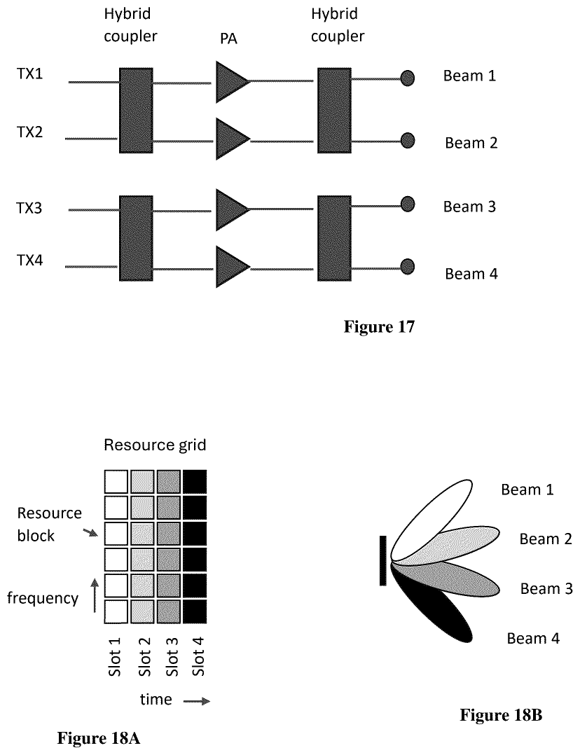

The balanced amplifier is well suited for beam switching with two beam states. For four beams, two balanced amplifiers are required (per polarization), as shown in FIG. 17. The first balanced amplifier connects to beam 1 and beam 2. The second balanced amplifier connects to beam 3 and beam 4. The key feature is that only one beam per balanced amplifier is active. When the second polarization is considered, two additional balanced amplifiers are used with the same beam pairing as shown in FIG. 17.

The scheduling of RBs for a beam sweep is shown in FIG. 18. Only one beam is active in each slot. The 8-port powered device (quad balanced amplifier), shown in either FIG. 9 or FIG. 10, is well suited for this application.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

Unless the context dictates the contrary, all ranges set forth herein should be interpreted as being inclusive of their endpoints, and open-ended ranges should be interpreted to include commercially practical values. Similarly, all lists of values should be considered as inclusive of intermediate values unless the context indicates the contrary.

The recitation of ranges of values herein is merely intended to serve as a shorthand method of referring individually to each separate value falling within the range including endpoints, as well as interstitial ranges between each separate value within the range. Unless otherwise indicated herein, each individual value is incorporated into the specification as if it were individually recited herein.

All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

This discussion provides many example embodiments of the inventive subject matter. Although each embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification or claims refer to at least one of something selected from the group consisting of A, B, C . . . . And N, the text should be interpreted as requiring only one element from the group, not A plus N, or B plus N, etc.

What is claimed is:

19. An antenna system with a plurality of fixed beams, wherein a subset of the fixed beams is inactive at any given time, the system comprising:
a distributed unit (DU) that transmits digital data through a plurality of radio units (Rus);
a first radio unit (RU) of the plurality of Rus having a plurality of transceivers that convert each of a plurality of digital channels into a low power RF signal; and
a powered device having a plurality of input and output ports and a plurality of power amplifier (PAs), the powered device configured such that (i) a path between each input port and associated output port forms a RF path and (ii) more than one PA concurrently contributes power to an active digital channel selected from the plurality of digital channels.

2. The system of claim 1, wherein the active digital channel is defined by the distributed unit (DU).

3. The system of claim 1, wherein the active digital channel is defined by the radio unit (RU).

4. The system of claim 1, wherein the powered device further comprises a balanced amplifier that includes an input hybrid coupler, a first and a second PA, and an output hybrid coupler.

5. The system of claim 4, wherein the input hybrid coupler is defined in a digital domain.

6. The system of claim 4, wherein the input hybrid coupler is defined in a RF domain.

7. The system of claim 1, wherein the plurality of fixed beams pass through a lens beamformer.

8. The system of claim 1, wherein the powered device has four input ports and four output ports, the powered device further comprising four input hybrid couplers, four PAs, and four output hybrid couplers.

9. The system of claim 8, wherein one of the input hybrid couplers is defined in the digital domain.

10. The system of claim 8, wherein one of the input hybrid couplers is defined in the RF domain.

11. The system of claim 1, wherein the powered device has four input ports and four output ports, the powered device further comprising an input Butler matrix, four PAs, and an output Butler matrix.

12. The system of claim 11, wherein the input Butler Matrix is defined in the digital domain.

13. The system of claim 11, wherein the input Butler Matrix is defined in the RF domain.

14. A system with a plurality of fixed beams, a powered device configured to receive or transmit a plurality of channels, and a digital modifier, the powered device comprising:
a plurality of pairs of input and output ports, where a path between each pair of input and output ports form a RF path;
a plurality of power amplifiers (PAs) disposed inside the powered device, wherein more than one PA from the plurality of PAs contributes power when one channel from the plurality of channels is active; and
a directional coupler coupled with each of the plurality of output ports and configured to measure an imbalance between each path;
wherein the digital modifier compensates for the imbalances of the powered device.

15. The system of claim 14, wherein the digital modifier uses a precoder matrix of a distributed unit (DU) coupled with the power device.

16. The system of claim 14, wherein the digital modifier is part of a radio unit (RU) transceiver.

17. The system of claim 14, wherein the powered device is a balanced amplifier comprising an input hybrid coupler, more than one power amplifier (PA), and an output hybrid coupler.

18. The system of claim 17, wherein the input hybrid coupler is defined in the digital domain.

19. The system of claim 14, wherein the plurality of fixed beams pass through a lens beamformer.
